(19) United States
(12) Patent Application Publication
(10) Pub. No.: US 2026/0179812 A1
(43) Pub. Date: Jun. 25, 2026

(54) METHOD FOR MAKING HIGH-RESISTANCE VALUE COAXIAL SHUNT AND CURRENT DETECTION SYSTEM

(71) Applicant: Shenzhen Zhiyong Electronics Co., Ltd., Shenzhen (CN)

(72) Inventors: Xiaoming Fan, Shenzhen (CN); Jiawei Fan, Shenzhen (CN)

(21) Appl. No.: 18/989,124

(22) Filed: Dec. 20, 2024

(51) Int. Cl. H01C 17/00; G01R 3/00; G01R 15/14; G01R 19/00

(52) U.S. Cl. CPC H01C 17/00; G01R 3/00; G01R 15/146; G01R 19/0092

(57) ABSTRACT

Provided is a method for making a high-resistance value coaxial shunt, including providing resistor bodies, the resistor bodies being provided in a stacked manner, and a conducting length of each of the resistor bodies being greater than the physical length of the resistor bodies in a stacked state. According to the method for making a high-resistance value coaxial shunt provided by the present disclosure, by providing the resistor bodies as the stacked structure, the conducting length of the resistor bodies can be effectively prolonged so that in the case that the conducting area and the physical length of the resistor bodies are not changed, the magnitude of the resistance is increased. The present disclosure further provides a current detection system.

### TECHNICAL FIELD

The present disclosure relates to the technical field of electronic circuit detection and particularly relates to a high-performance coaxial shunt and a current detection system.

### BACKGROUND

In the field of electronic measurement, it is often needed to measure a high-frequency current wave (above 100 MHz). In order to reduce the parasitic inductance of a shunt, a coaxial shunt is generally used in the industry to detect a high-frequency current. The working principle of the coaxial shunt is mainly based on Ohm's law, which measures a current precisely by measuring the relationship between the current and the voltage. Specifically, the coaxial shunt has a special resistance value. When the current passes through the coaxial shunt, corresponding voltage drops will be generated at both ends of the shunt, and these voltage drops are in direct proportion to the passing current. Therefore, the resistance value in the coaxial shunt is relatively important for detection. It is needed to design and make the coaxial shunt in advance according to a measured and detected current value or voltage value range.

However, in the prior art, subject to the influence of the size dimension and resistance material, the resistance value of the coaxial shunt is generally less, which is usually between 0.01 ohm and 0.1 ohm. Therefore, the resistance value hardly meets the requirement of detection precision, particularly detection on a low-voltage, high-frequency current.

### SUMMARY

The present disclosure provides a method for making a high-resistance value coaxial shunt and a current detection system to solve the above problem of small resistance value so as to increase the detection resistance value and expand the range of application.

The present disclosure provides a method for making a high-resistance value coaxial shunt, including the following steps:

S1: providing resistor bodies, the resistor bodies being provided in a stacked manner and a conducting length of each of the resistor bodies being greater than the physical length of the resistor bodies in a stacked state;

S2: providing an outer conductor, an accommodating cavity being provided in the outer conductor;

S3: providing a center shaft conductor, the center shaft conductor penetrating through the outer conductor, and the resistor bodies and the center shaft conductor both being of cylindrical structures and coaxially provided from outside to inside; and

S4: accommodating each of the resistor bodies in the accommodating cavity and connecting the resistor bodies to the center shaft conductor and the outer conductor.

The present disclosure provides a current detection system, including a detection device and a high-resistance value coaxial shunt. The high-resistance value coaxial shunt includes an outer conductor, a center shaft conductor, and resistor bodies. An accommodating cavity is provided in the outer conductor, the center shaft conductor penetrates through the outer conductor, the resistor bodies are accommodated in the accommodating cavity, and the outer conductor, the resistor bodies, and the center shaft conductor all are of cylindrical structures and coaxially provided from outside to inside; the resistor bodies are provided of a stacked structure, and a conducting length of each of the resistor bodies is greater than a physical length of the resistor bodies in a stacked state; and the detection device is electrically connected to the outer conductor and the center shaft conductor.

Compared with the prior art, according to the method for making a high-resistance value coaxial shunt provided by the present disclosure, by providing the resistor bodies as the stacked structure, the conducting length of the resistor bodies can be effectively prolonged so that in the case that the conducting area and the physical length of the resistor bodies are not changed, the magnitude of the resistance is increased; the stacked arrangement mode will not cause the increase of the length of the high-resistance value coaxial shunt, and moreover, the stacked arrangement utilizes the accommodating cavity effectively without increasing the volume of the high-resistance value coaxial shunt.

The method for making a high-resistance value coaxial shunt is simple. Compared with the prior art, the longer resistor bodies are provided, and then the resistor bodies are provided in a stacked manner, which not only effectively increases the resistance value of the resistor bodies. The whole generation and processing course is quite convenient.

In addition, according to the current detection system provided by the present disclosure, the high-resistance value coaxial shunt used is made by the method for making the high-resistance value coaxial shunt. By effectively increasing the resistance values of the resistor bodies, low-voltage high-frequency current signals can be measured, the range of application of the current detection system is expanded, and the precision of detecting high-voltage high-frequency current signals can be effectively improved.

### BRIEF DESCRIPTION OF DRAWINGS

In order to describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without making creative efforts.

FIG. 1 is a structural block diagram of a current detection system provided by the present disclosure;

FIG. 2 is a three-dimensional schematic structural diagram of a high-resistance value coaxial shunt provided in the first embodiment of the present application;

FIG. 3 is a three-dimensional structural exploded view of the high-resistance value coaxial shunt provided in the first embodiment of the present application;

FIG. 4 is a sectional view of the high-resistance value coaxial shunt provided in the first embodiment of the present application;

FIG. 5 is an enlarged sectional view of a resistor provided in a second embodiment of the present application;

FIG. 6 is an enlarged sectional view of a resistor provided in a third embodiment of the present application; and

FIG. 7 is an enlarged sectional view of a resistor provided in a fourth embodiment of the present application.

### DESCRIPTION OF EMBODIMENTS

The following clearly and completely describes the technical solutions in the embodiments of the present disclosure with reference to the accompanying drawings in the embodiments of the present disclosure. Apparently, the described embodiments are some of the embodiments of the present disclosure rather than all of the embodiments. Based on the embodiments in the present disclosure, all other embodiments acquired by those of ordinary skill in the art without making creative efforts fall within the scope of protection of the present disclosure.

It should be noted that all directional indications (for example, upper, lower, left, right, front, back, and the like) in the embodiment of the present disclosure are merely used for explaining relative position relations, moving conditions, and the like among components in a certain special gesture (as shown in the drawings). If the special gesture changes, the directional indications change correspondingly.

In addition, descriptions such as "first" and "second" are merely used for a description purpose rather than being construed as indicating or implying relative importance or implicitly indicating the quantity of indicated technical features. Thus, features defining "first" and "second" may expressively or implicitly include at least one feature. In the description of the present disclosure, unless otherwise specified, "a plurality of" means at least two, for example, two, three, and the like.

In the present disclosure, unless otherwise expressly stated and defined, the terms "connect", "fix" and the like shall be understood in a broad sense. For example, "fix" may be fixed connected or detachably connected, or integrally connected; they may be mechanically connected or electrically connected; they may be directly connected or connected via an intermediate, or they may communicate between two components insides or an interactive relation of the two components unless otherwise specified. Those of ordinary skill in the art can understand the specific meaning of the terms in the present disclosure under specific circumstances.

In addition, the technical solutions of the embodiments of the present disclosure may be combined with one another based on implementation by those of ordinary skill in the art. When the technical solutions contradict each other in combination or may not be realized, it is to be considered that there is no combination of the technical solutions, which shall not fall into the protection scope of the present disclosure.

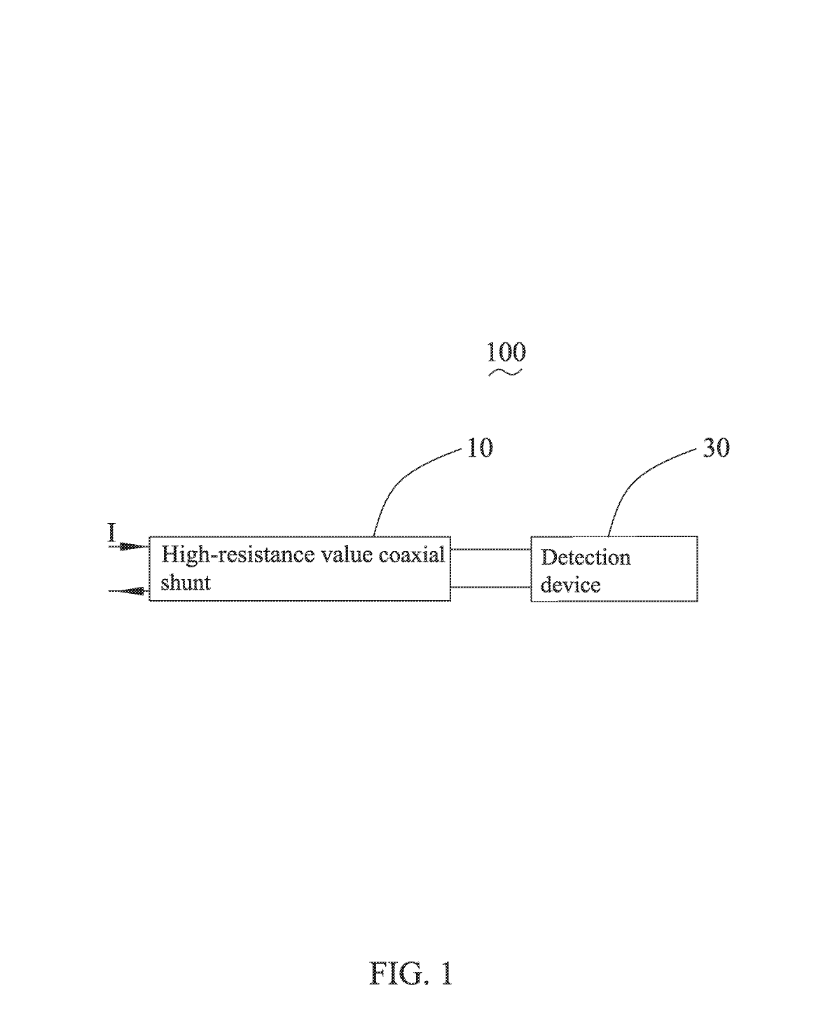

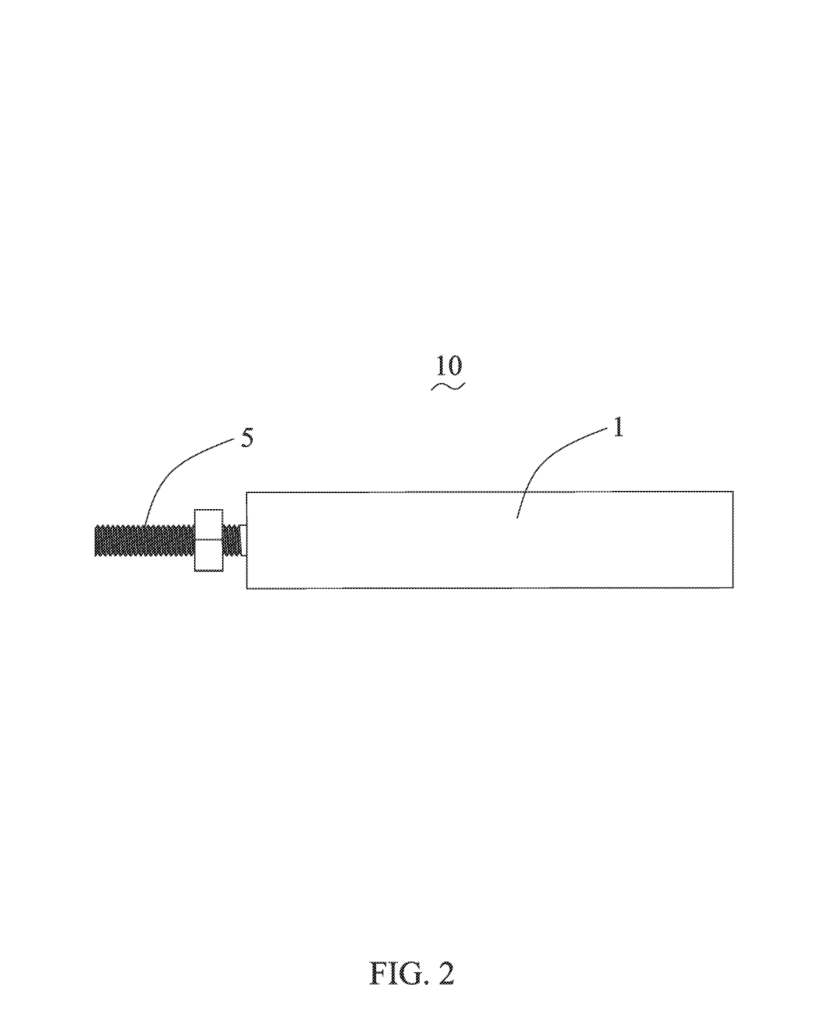

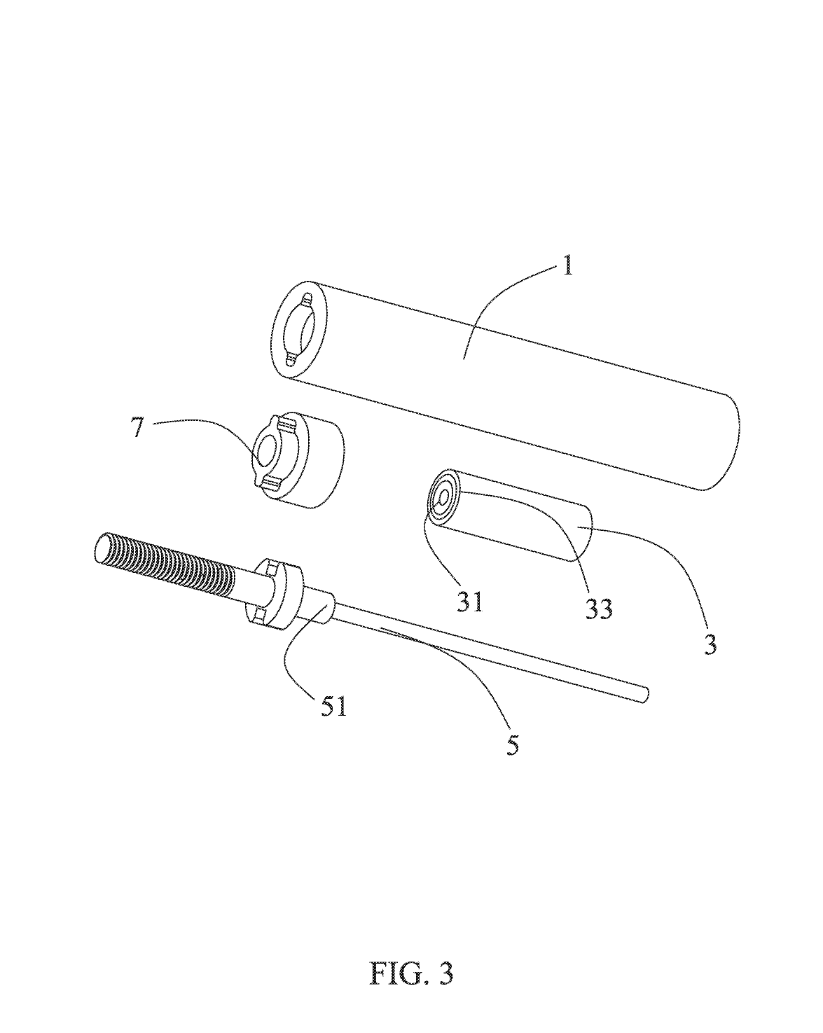

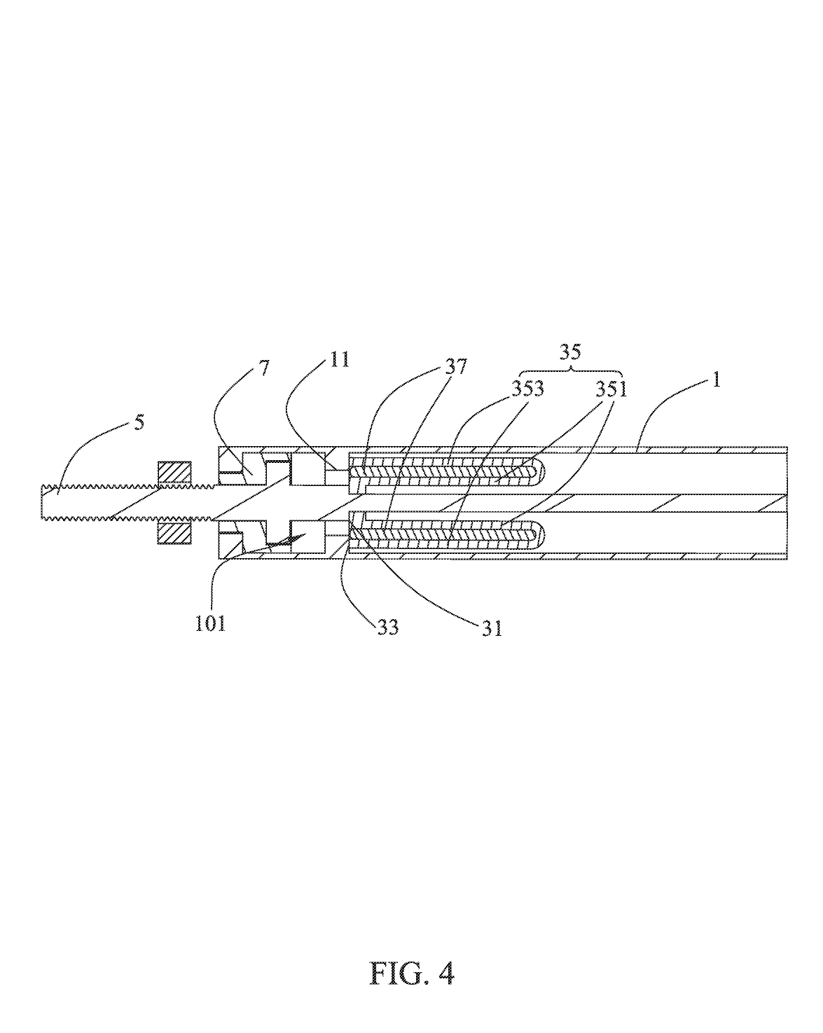

Referring to FIGS. 1-4 at the same time, the current detection system 100 includes a detection device 30 and a high-resistance value coaxial shunt 10. A method for making the high-resistance value coaxial shunt 10 includes the following steps:

S1: providing resistor bodies 3, the resistor bodies 3 being provided in a stacked manner 3 and a conducting length of each of the resistor bodies 3 being greater than the physical length of the resistor bodies in a stacked state;

S2: providing an outer conductor 1, an accommodating cavity 101 being provided in the outer conductor 1;

S3: providing a center shaft conductor 5, the center shaft conductor 5 penetrating through the outer conductor 1, and the resistor bodies 3 and the center shaft conductor 5 both being of cylindrical structures and coaxially provided from outside to inside; and

S4: accommodating each of the resistor bodies 3 in the accommodating cavity 101, and connecting the resistor bodies to the center shaft conductor 5 and the outer conductor 1.

The detection device 30 is electrically connected to the outer conductor 1 and the center shaft conductor 5 for detecting high-frequency current signals.

In the high-resistance value coaxial shunt 10, the resistor bodies 3 are provided as the stacked structure, so that the conductive length of each of the resistor bodies 3 is prolonged. It could be known from a computational formula R=ρoL/S of resistance, in the case of an unchanged material, in order to increase the resistance value of each of the resistor bodies 3, the conductive length may be increased or the area where the current passes may be decreased. However, the thickness of each of the resistor bodies 3 in the prior art is at least 10 microns, and the resistor bodies are easily broken if they are made thinner. Therefore, by providing the resistor bodies 3 in a stacked manner, in the case that the physical length of each of the resistor bodies 3 is not increased, the conductive length of each of the resistor bodies 3 is increased so that the resistance value of each of the resistor bodies 3 is increased.

In order to improve the reliability of the resistor bodies 3, each of the resistor bodies 3 further includes conductive film sheets 35 and insulation sheets 37. The conductive film sheets 35 are provided in a stacked manner to prolong the conductive length. Each of the conductive film sheets 35 includes a first conductive end 31 and a second conductive end 33, the first conductive end 31 being electrically connected to the center shaft conductor 5, and the second conductive end 33 being electrically connected to the outer conductor 1. Since the conductive film sheets 35 are provided in a stacked manner, a high-frequency current signal flowing on the conductive film sheets 35 flows in or out from the first conductive end 31 or the second conductive end 33 to form the conductive length, i.e., when the high-frequency current signal flows through the conductive film sheets, the length of the conductive film sheets 35 is inevitably greater than a linear distance between the first conductive end 31 and the second conductive end 33.

The insulation sheet 37 are attached to the conductive film sheet 35 to prevent the conductive film sheet 35 from being short-circuited. Since the conductive film sheets 35 are provided in a stacked manner, if they are adhered directly, a short circuit of the resistor bodies 3 is easily caused. The actual resistance value is not increased. Therefore, by providing the insulation sheets 37, the conductive film sheets 35 may be effectively provided in a stacked manner at an interval, so that the resistance value of each of the resistor bodies 3 is stable.

It should be noted herein that the conductive film sheet 35 may be made of constantan or manganin with good conductivity. Moreover, the thickness may be made less. Matched with a solution of stacked arrangement, the resistance value of each of the resistor bodies 3 is increased. Each of the insulation sheets 37 may be made of a polyimide film, so that each of the insulation sheets has a very good insulating property. The thickness may also be less. Each of the insulation sheets adheres to each of the conductive film sheets 35, which will not result in a too large volume of each of the resistor bodies 3 as a whole so that the volume of each of the resistor bodies 3 is effectively controlled. The accommodating cavity 101 is formed in the outer conductor 1, and there is a certain space between the center shaft conductor 5 and the outer conductor 1, so that each of the resistor bodies 3 may be provided. Therefore, in the case of effectively controlling the whole volume of each of the resistor bodies 3, the accommodating cavity 101 may be fully utilized, and the volume of the high-resistance value coaxial shunt 10 will not change.

In the first embodiment, each of the conductive film sheets 35 is integrally made, folded, and rolled into a barrel structure. Each of the insulation sheets 37 is adhered to each of the conductive film sheets 35. Each of the insulation sheets 37 is folded and rolled into a barrel structure together with each of the conductive film sheets 35. The arrangement mode is simple and skillful and convenient to process. It is only needed to make the conductive film sheets 35 large, then adhere the insulation sheets 37 in advance to the conductive film sheets 35, roll them into the barrel structures after being jointly folded, and then connect them to the center shaft conductor 5 and the outer conductor 1. The processing steps are few, and the arrangement mode is not prone to make mistakes.

Of course, the bending number of each of the resistor bodies 3 may be an odd number of times. Correspondingly, the layer number of the stacked conductive film sheet 35 is an even number; for example, the layer number is two if each of the resistor bodies is bent once; the layer number is four if each of the resistor bodies is bent three times, by parity of reasoning. In the first embodiment, each of the resistor bodies 3 is bent once. Each of the conductive film sheets 35 includes a first conductive section 351 and a second conductive section 353, the first conductive section 351 being provided with a first conductive end 31 and located on one side of each of the conductive film sheets 35 close to the outer conductor 5, the second conductive section 353 being provided with a second conductive end 33 and located on one side of each of the conductive film sheets 35 close to the outer conductor 1, the second conductive section 353 being coaxially provided together with the first conductive section 351, the outer conductor 1, and the center shaft conductor 5 all, and a flow direction of a current of the second conductive section 353 is opposite to a flow direction of a current of the first conductive section 351.

The high-resistance value coaxial shunt 10 provided in the first embodiment may increase the resistance value of each of the resistor bodies 3 to about two times, and each of the resistor bodies is only folded once so it is unlikely to have problems. This mode may be performed on the premise that the requirement on resistance increase of each of the resistor bodies 3 is not high. Moreover, since the first conductive section 351 and the second conductive section 353 are coaxially provided together with the outer conductor 1 and the center shaft conductor 5, high-frequency current signals passing through the first conductive section 351 and the second conductive section 353 may counteract interference of a magnetic field mutually.

It should be noted that since each of the conductive film sheets 35 is only folded once, each of the insulation sheets 37 may only adhere to one side of each of the conductive film sheets 35 to block the first conductive section 351 and the second conductive section 353, thereby preventing each of the conductive film sheets 35 from being short-circuited. The insulation sheet is not necessarily provided on the other side so the production and processing costs are lowered. Of course, in another embodiment, after the conductive film sheets 35 are folded, each of the insulation sheets 37 is clamped between two adjacent conductive film sheets 35, i.e., the insulation sheet 37 is clamped between the first conductive section 351 and the second conductive section 353. In a solution where each of the insulation sheets 37 and each of the conductive film sheets 35 are adhered and jointly folded, two insulation sheets 37 will be clamped between the first conductive section 351 and the second conductive section 353. In comparison, the way of independently clamping the insulation sheet 37, one insulation sheet 37 may be saved so that the production cost is further lowered.

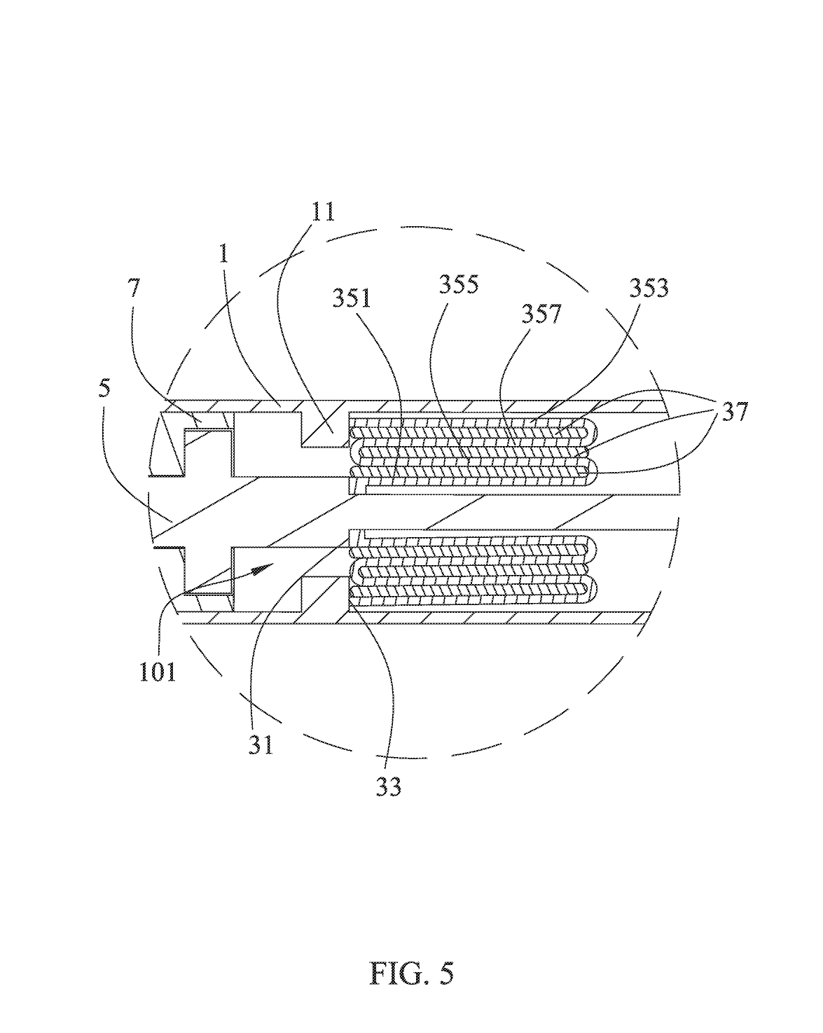

Continuously referring to FIG. 5, FIG. 5 is a sectional view of a method for making a high-resistance value coaxial shunt 10 provided in the second embodiment of the present application. In order to continuously increase the resistance value of each of the resistor bodies 3, each of the conductive film sheets 35 may be continuously folded. Each of the conductive film sheets 35 further includes at least one-third of conductive section 355 and at least one-fourth of conductive section 357, the third conductive sections 355 and the fourth conductive sections 357 being in one-to-one correspondence in quantity, provided in a stacked manner between the first conductive section 351 and the second conductive section 353 at an interval, and coaxially provided together with the first conductive section 351 and the second conductive section 353, and a flow direction of a current of each of the third conductive sections 355 is opposite to flow directions of a current of the first conductive section 351 and the fourth conductive sections 357.

Three times are taken as an example herein. The high-resistance value coaxial shunt 10 provided in the second embodiment may increase the resistance value of each of the resistor bodies 3 to about four times. Each of the resistor bodies 3 is bent three times. Compared with the first embodiment, each of the conductive film sheets 35 includes the first conductive section 351, the second conductive section 353, the third conductive section 355, and the fourth conductive section 357. Since they are all coaxially provided to counteract interference of the magnetic field, the length or volume of the high-resistance value coaxial shunt 10 will not be increased. Of course, in the embodiment, if each of the insulation sheets 37 is adhered and folded successively, it is needed to adhere the insulation sheets on both sides of each of the conductive film sheets 35, so as to prevent a short circuit; and similarly, the insulation sheets 37 may also be additionally provided in an independent clamping manner, so that the processing cost may be greatly lowered.

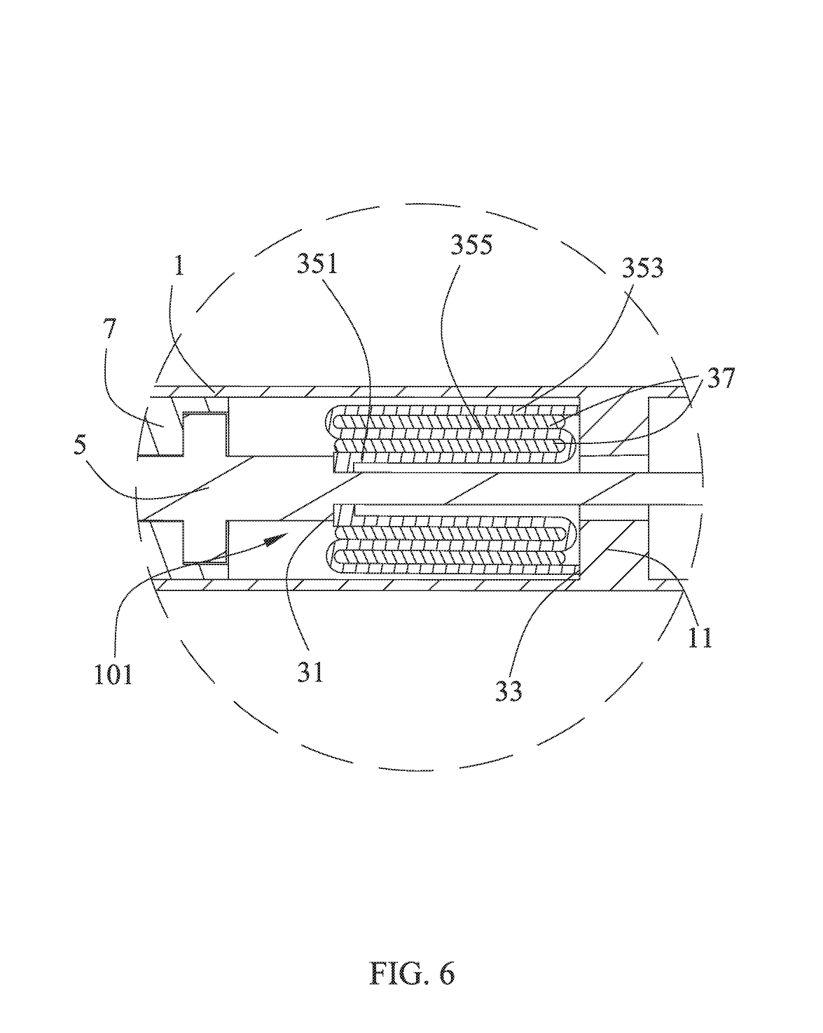

Continuously referring to FIG. 6, FIG. 6 is a sectional view of a method for making a high-resistance value coaxial shunt 10 provided in the third embodiment of the present application. In order to facilitate the mounting of each of the resistor bodies 3, the bending number of times of each of the resistor bodies 3 is an odd number of times. Each of the conductive film sheets 35 includes a first conductive section 351, a second conductive section 353, and a third conductive section 355, the first conductive section 351 being provided with a first conductive end 31 and located on one side of each of the conductive film sheets close to the outer conductor 5, the second conductive section 353 being provided with a second conductive end 33 and located on one side of each of the conductive film sheets close to the outer conductor 1, the third conductive section 355 and the second conductive section 353 both being coaxially provided together with the first conductive section 351, the outer conductor 1, and the center shaft conductor 5, the third conductive section 355 being provided between the second conductive section 353 and the first conductive section 351, and a flow direction of a current of the third conductive section 355 is opposite to flow directions of a current of the second conductive section 353 and the first conductive section 351.

Taking folding twice as an example, the high-resistance value coaxial shunt 10 provided in the third embodiment may increase the resistance value of each of the resistor bodies 3 to about three times. Both ends of each of the third conductive section 355 are respectively connected to the first conductive section 351 and the second conductive section 353. It may be seen from the sectional view that the first conductive end 31 and the second conductive end 33 are not provided on the same side. Compared with the first embodiment and the second embodiment, the arrangement mode of the third embodiment facilitates the mounting of each of the resistor bodies 3. The second conductive end 33 may abut against the outer conductor 1, so that each of the resistor bodies 3 is effectively mounted and fixed. Moreover, the distance between the first conductive end 31 and the second conductive end 33 is relatively long, and the first conductive end and the second conductive end hardly have contact with each other, so the reliability of each of the resistor bodies 3 is improved.

Correspondingly, the first conductive section 351, the second conductive section 353, the third conductive section 355, and the outer conductor 1 may counteract interference of the magnetic field mutually, which does not affect the normal use of the high-resistance value coaxial shunt 10. Of course, the arrangement mode of each of the insulation sheets 37 may also be adhering and folding successively or an independent clamping mode, which is not described in detail herein.

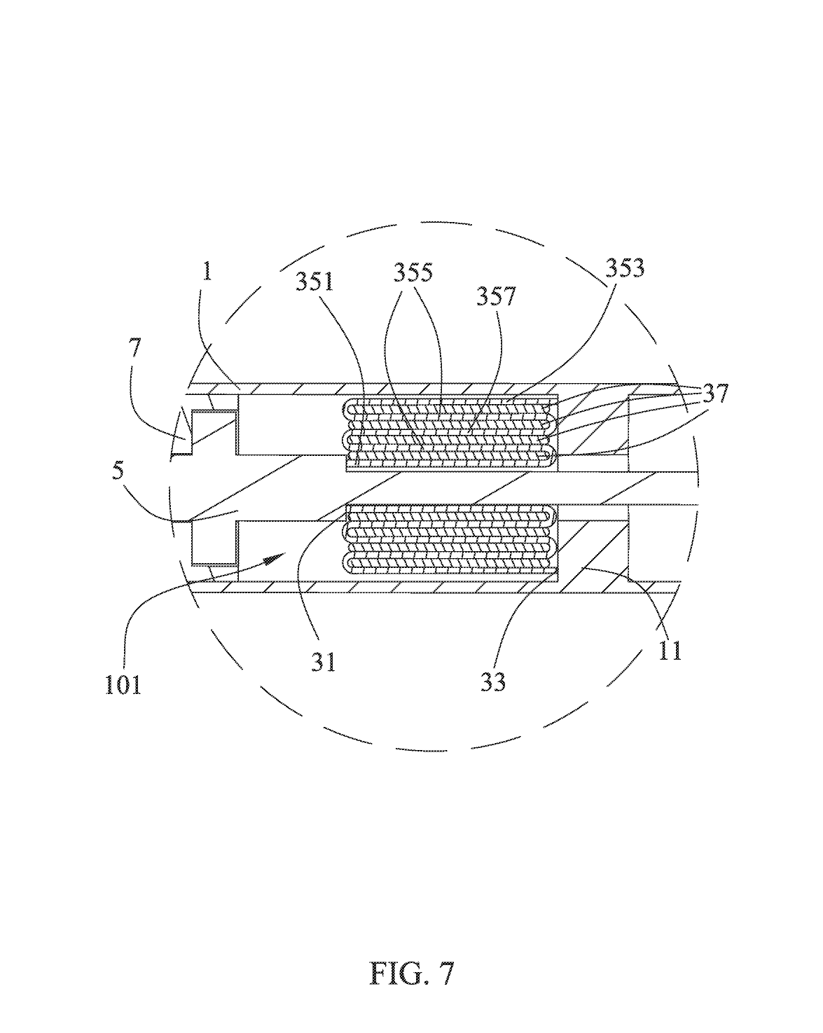

Continuously referring to FIG. 7, FIG. 7 is a sectional view of a method for making a high-resistance value coaxial shunt 10 provided in the fourth embodiment of the present application. In order to continuously increase the resistance value of each of the resistor bodies 3, each of the conductive film sheets 35 further includes at least one-fourth of conductive section 357, there being one more third conductive section 355 than the fourth conductive section 357, the fourth conductive section 357 being clamped between two adjacent third conductive sections 355, and a flow direction of a current of the fourth conductive section 357 is opposite to flow directions of a current of the second conductive section 353 and the first conductive section 351.

In the fourth embodiment, each of the resistor bodies 3 is folded four times, and the high-resistance value coaxial shunt 10 may increase the resistance value of each of the resistor bodies 3 to about five times. Each of the conductive film sheets 35 includes one first conductive section 351, one second conductive section 353, two third conductive sections 355, and one fourth conductive section 357. Both ends of the fourth conductive section 357 are respectively connected to the outer third conductive section 355 and the inner third conductive section 355, the outer third conductive section 355 is connected to the second conductive section 353, the inner third conductive section 355 is connected to the first conductive section 351, and the first conductive section 351, the second conductive section 353, the two third conductive section 355, the fourth conductive section 357, and the outer conductor 1 may counteract interference of the magnetic field mutually, so that normal use of the high-resistance value coaxial shunt 10 is not affected. Of course, the arrangement mode of each of the insulation sheets 37 may also be adhering and folding successively or an independent clamping mode, which is not described in detail herein.

Therefore, the resistance value of each of the resistor bodies 3 can be effectively improved from the first embodiment to the fourth embodiment. In the production and manufacturing processes, the folding number of times may be selected according to actual demand, and the conductive film sheets 35 and insulation sheets 37 are correspondingly provided. In the above embodiments, by integrally providing the conductive film sheets 35, the conductive film sheets are folded and rolled to make the resistor bodies 3.

It should be noted herein that in another embodiment, the two conductive film sheets 35 are provided on each of the resistor bodies 3, the conductive film sheets 35 are provided in a stacked manner, and one side of the two adjacent conductive film sheets 35 are electrically connected, so that the conductive length of each of the conductive film sheets 35 is prolonged; and each of the insulation sheet 37 is clamped between the two adjacent conductive film sheets 35. In the embodiment, each of the conductive film sheets 35 is directly adhered to without being bent to form and then rolled into the barrel structure. The adjacent conductive film sheets 35 are electrically connected by way of welding. This arrangement mode may enable the conductive film sheets 35 to be unlikely to be damaged or broken at the bent position so that the stability of each of the resistor bodies 3 is improved. Moreover, according to the demand on the resistance value of each of the resistor bodies 3, the quantity of the conductive film sheets 35 may be set flexibly. Of course, a conductive path and a layout mode of each of the conductive film sheets 35 may refer to the above embodiments, which are not repeatedly described herein.

It should be mainly noted herein that the conductive length of each of the resistor bodies 3 is L in the resistance computational formula R=ρ•L/S. In the above embodiment, it refers to the length of each of the conductive film sheets 35 which the high-frequency current signal flows through. The description is made by taking the fourth embodiment as an example. The high-frequency current signal flows through the first conductive section 351, the inner third conductive section 355, the fourth conductive section 357, the inner third conductive section 355, and the second conductive section 353 successively, and the conductive length is the sum of the lengths of the above five conductive sections. Correspondingly, the physical length of each of the resistor bodies 3 in the stacked state refers to the length of each of the resistor bodies 3 in physical space, which is equivalent to the length of one conductive film sheet 35 or one conductive section. Compared with the conductive length, the two differ by nearly 4 times.

In addition, in order to facilitate mounting of each of the resistor bodies 3, the outer conductor 1 is provided with an annular flange 11 matching with each of the resistor bodies 3 to abut against the second conductive end 33. The outer conductor 1 matches with the center shaft conductor 5 through flange 11 to fix the position of each of the resistor bodies 3. Of course, if each of the insulation sheets 37 covers the bending position of each of the conductive film sheets 35, one side of each of the resistor bodies 3 may abut against the flange 11 completely. If not, a short circuit of each of the resistor bodies 3 may be caused. Therefore, it may only be that the second conductive end 33 is electrically connected to the flange 11. Similarly, the center shaft conductor 5 may also be provided with corresponding flange 11 to match with each of the resistor bodies 3 so as to abut against the first conductive end 31, which is not described in detail herein.

In order to further protect each of the resistor bodies 3, an insulating part 7 may further be provided between the outer conductor 1 and the center shaft conductor 5. The insulating part 7 may clamp the outer conductor 1 and the center shaft conductor 5 at the same time, so that the outer conductor 1 and the center shaft conductor 5 will not displace relative to each other. Since the plurality of conductive film sheets 35 is provided in a stacked manner, the whole structure of each of the resistor bodies 3 is fragile. If a displacement in a rotary or linear direction is formed between the outer conductor 1 and the center shaft conductor 5, each of the resistor bodies 3 is easily damaged. By providing the insulating part 7, the safety of each of the resistor bodies 3 may be effectively improved, and the service life of the high-resistance value coaxial shunt 10 is prolonged.

The above is merely an exemplary implementation of the present disclosure. It is to be noted that those of ordinary skill in the art may make improvements without departing from the concept of the present disclosure and the improvements shall fall within the protection scope of the present disclosure.

What is claimed is:

1. A method for making a high-resistance value coaxial shunt, comprising the following steps:
S1: providing resistor bodies, the resistor bodies being provided in a stacked manner and a conducting length of each of the resistor bodies being greater than the physical length of the resistor bodies in a stacked state;
S2: providing an outer conductor, an accommodating cavity being provided in the outer conductor;
S3: providing a center shaft conductor, the center shaft conductor penetrating through the outer conductor, and the resistor bodies and the center shaft conductor both being of cylindrical structures and coaxially provided from outside to inside; and
S4: accommodating each of the resistor bodies in the accommodating cavity, and connecting the resistor bodies to the center shaft conductor and the outer conductor.

2. The method for making a high-resistance value coaxial shunt according to claim 1, wherein in S1, each of the resistors comprises:
conductive film sheets, the conductive films being provided in a stacked manner for prolonging the conducting length, each of the conductive film sheets comprising a first conductive end and a second conductive end, the first conductive end being electrically connected to the center shaft conductor, and the second conductive end being electrically connected to the outer conductor; and
insulation sheets, the insulation sheets being attached to the conductive film sheets to prevent the conductive film sheets from being short-circuited.

3. The method for making a high-resistance value coaxial shunt according to claim 2, wherein in S1, each of the conductive film sheets is integrally made and folded and rolled into a barrel structure;
each of the insulation sheets is adhered to each of the conductive film sheets and is folded and rolled into a barrel structure with each of the conductive film sheets; or, after each of the conductive film sheets is folded, each of the insulation sheets is clamped between two adjacent conductive film sheets.

4. The method for making a high-resistance value coaxial shunt according to claim 2, wherein the bending number of times of each of the resistor bodies is an odd number of times; and each of the conductive film sheets comprises:
a first conductive section, the first conductive section being provided with the first conductive end and located on one side of each of the conductive film layers close to the center shaft conductor; and
a second conductive section, the second conductive section being provided with a second conductive end and located on one side of each of the conductive film layers close to the outer conductor, the second conductive section, the first conductive section, the outer conductor, and the center shaft conductor all being coaxially provided, and a flow direction of a current of the second conductive section is opposite to a flow direction of a current of the first conductive section.

5. The method for making a high-resistance value coaxial shunt according to claim 4, wherein each of the conductive film sheets further comprises at least one-third conductive section and at least one-fourth conductive section, the third conductive sections and the fourth conductive sections being in one-to-one correspondence in quantity, being provided in a stacked manner between the first conductive section and the second conductive section at an interval, and coaxially provided together with the first conductive section and the second conductive section, and a flow direction of a current of each of the third conductive sections is opposite to flow directions of a current of the first conductive section and the fourth conductive sections.

6. The method for making a high-resistance value coaxial shunt according to claim 2, wherein the bending number of times of each of the resistor bodies is an even number of times; and each of the conductive film sheets comprises:
a first conductive section, the first conductive section being provided with the first conductive end and located on one side of each of the conductive film layers close to the center shaft conductor;
a second conductive section, the second conductive section being provided with the second conductive end and located on one side of each of the conductive film layers close to the outer conductor; and
a third conductive section, the third conductive section, the second conductive section, the first conductive section, the outer conductor, and the center shaft conductor all being coaxially provided, the third conductive section being provided between the second conductive section and the first conductive section, and a flow direction of a current of the third conductive section is opposite to flow directions of a current of the second conductive section and the first conductive section.

7. The method for making a high-resistance value coaxial shunt according to claim 6, wherein each of the conductive film sheets further comprises at least one-fourth conductive section, there being one more third conductive section than the fourth conductive section, the fourth conductive section being clamped between two adjacent third conductive sections, and a flow direction of a current of the fourth conductive section is opposite to flow directions of a current of the second conductive section and the first conductive section.

8. The method for making a high-resistance value coaxial shunt according to claim 2, wherein in S1, each of the resistors is provided with at least two conductive film sheets, the conductive film sheets being provided in a stacked manner, and the sides between the two adjacent conductive film sheets being electrically connected to prolong the conductive length of the conductive film sheets; and
each of the insulation sheets is clamped between the two adjacent conductive film sheets.

9. The method for making a high-resistance value coaxial shunt, according to claim 1, wherein the outer conductor is provided with an annular flange matching with each of the resistor bodies to abut against the second conductive end.

10. A current detection system, comprising:
a detection device; and
a high-resistance value coaxial shunt, the high-resistance value coaxial shunt being made by the method for making a high-resistance value coaxial shunt according to claim 1, and the detection device being electrically connected to the outer conductor and the center shaft conductor.
